(19) United States
(12) Patent Application Publication
(10) Pub. No.: US 2016/0232847 A1
(43) Pub. Date: Aug. 11, 2016

(54) Scan Control Line Driving Module and Display Device Including Same

(71) Applicant: EverDisplay Optronics (Shanghai) Limited, Shanghai (CN)

(72) Inventor: Ching-Hung Lee, Shanghai (CN)

(73) Assignee: EverDisplay Optronics (Shanghai) Limited

(21) Appl. No.: 14/808,341

(22) Filed: Jul. 24, 2015

(30) Foreign Application Priority Data
Feb. 6, 2015 (CN) 201510061323.6

(51) Int. Cl. G09G 3/32

(52) U.S. Cl. CPC G09G 3/3258; G09G 2310/08; G09G 2310/0213; G09G 2300/0426; G09G 2310/0216

(57) ABSTRACT

A scan control line driving module and a display device. The scan control line driving module includes a first grade scan control line driving unit for receiving a first timing sequence control signal outputted by a timing sequence controller and for outputting a first grade scan signal to a panel display module and a second grade scan control line driving unit. The second grade scan control line driving unit receives a second timing sequence control signal from the timing sequence controller and the first grade scan signal from the first grade scan control line driving unit. The second grade scan control line driving unit outputs a second grade scan signal to the panel display module and a scan control line driving unit of the next grade. Each scan control line driving unit includes only two control input ends to save the space for wires.

### CROSS-REFERENCE TO RELATED APPLICATION

This application claims the benefit of priority to CN 201510061323.6, filed on Feb. 6, 2015 with the State Intellectual Property Office of the People's Republic of China, the entire specification of which is incorporated herein by reference.

### BACKGROUND OF THE INVENTION

The present invention relates to a scan control line driving module and a display device including the scan control line driving module and, more particularly, to a scan control line driving module for an organic light-emitting diode (OLED) and a display device including the scan control line driving module.

With the development of the display technology, the developing trends of display devices are larger size, higher resolution, narrower frame, and 3D display.

With regard to the narrow frame designs, the frame of a display device is mainly used to receive chips and circuits. Thus, the width of the frame can be greatly reduced if the scan control line driving circuits in the frame can be simplified. The primary research motive of the present invention is how to simplify the scan signal generating circuits while maintaining the function of stable scan signal output. However, the scan control line driving circuits of the current technology adopt a complicated control approach in which each scan control line driving circuit includes many control ends most of which require independent control lines, and these control lines occupy a considerable space for wires.

### BRIEF SUMMARY OF THE INVENTION

An objective of the present invention is to provide a scan control line driving module and a display device including the scan control line driving module to solve the problem of complicated control of the conventional scan control line driving module.

To fulfill the above objective, the present invention provides a scan control line driving module including a timing sequence controller, a first grade scan control line driving unit, a second grade scan control line driving unit, and a third grade scan control line driving unit. The timing sequence controller is adapted to output a first timing sequence control signal and a second timing sequence control signal.

The first grade scan control line driving unit includes a first timing sequence control end and a second timing sequence control end, the first timing sequence control end of the first grade scan control line driving unit receives the first timing sequence control signal, the second timing sequence control end of the first grade scan control line driving unit receives the second timing sequence control signal, and the first grade scan control line driving unit outputs a first grade scan signal to the second grade scan control line driving unit.

The second grade scan control line driving unit includes a first timing sequence control end and a second timing sequence control end, the first timing sequence control end of the second grade scan control line driving unit receives the second timing sequence control signal, the second timing sequence control end of the second grade scan control line driving unit receives the first timing sequence control signal, and the second grade scan control line driving unit outputs a second grade scan signal to the third grade scan control line driving unit.

The third grade scan control line driving unit includes a first timing sequence control end and a second timing sequence control end, the first timing sequence control end of the third grade scan control line driving unit receives the first timing sequence control signal, the second timing sequence control end of the third grade scan control line driving unit receives the second timing sequence control signal, and the third grade scan control line driving unit outputs a scan signal.

The timing sequence controller can include a first clock signal line for outputting a first clock signal and a second clock signal line for outputting a second clock signal. The first and second clock signal lines are square signals having an identical frequency and having a phase difference of 180°.

Each of the first grade scan control line driving unit, the second grade scan control line driving unit, and the third grade scan control line driving unit can include a signal input end, a scan control line driving circuit, and a signal output end. The scan control line driving circuit is adapted to conduct a delay processing of a signal received from the signal input end under control of the first timing sequence control signal and the second timing sequence control signal. The processed signal is outputted via the signal output end.

The scan control line driving circuit can include a control module. The control module includes:

a first transistor including a source, a gate, and a drain, with the source of the first transistor connected to a first power, and with the gate of the first transistor connected to the signal input end;

a second transistor including a gate, a source, and a drain, with the drain of the first transistor connected to the gate of the second transistor, and with the source of the second transistor connected to a first reset signal end;

a third transistor including a source, a drain, and a gate, with the source of the third transistor connected to the gate of the second transistor, with the drain of the third transistor connected to a second power, and with the gate of the third transistor connected to the first timing sequence control end;

a third capacitor having two ends respectively connected to the gate and the drain of the second transistor; and

a fourth transistor including a source, a drain, and a gate, with the drain of the second transistor connected to the source of the fourth transistor, and with the gate and the drain of the fourth transistor connected to second timing sequence control end.

The scan control line driving circuit can further include an output reset module. The output reset module includes:

a fifth transistor including a source, a gate, and a drain, with the source of the fifth transistor connected to the first power, with the gate of the fifth transistor connected to the first reset signal end, with the drain of the fifth transistor connected to a second reset signal end;

a sixth transistor including a source, a gate, and a drain, with the source of the sixth transistor connected to the first power, with the gate of the sixth transistor connected to the first set signal end, with the drain of the sixth transistor connected to the drain of the fifth transistor;

a second capacitor having two ends respectively connected to the source and the drain of the sixth transistor; and

a seventh transistor including a source, a gate, and a drain, with the source of the seventh transistor connected to the first power, with the gate of the seventh transistor connected to the drain of the sixth transistor, and with the drain of the seventh transistor connected to the signal output end.

The scan control line driving circuit can further include an output set module. The output set module includes:

an eighth transistor including a source, a gate, and a drain, with the source of the eighth transistor connected to the signal output end, with the drain of the eighth transistor connected to the first timing sequence control end;

a ninth transistor including a source, a gate, and a drain, with the gate of the eighth transistor connected to the drain of the ninth transistor, with the gate of the ninth transistor connected to a second power;

a first capacitor having two ends respectively connected to the source and the gate of the eighth capacitor;

a tenth transistor including a source, a gate, and a drain, with the source of the ninth transistor connected to the drain of the tenth transistor, with the gate of the tenth transistor connected to the second power source, and with the source of the tenth transistor connected to the second reset signal end and the first set signal end; and

an eleventh transistor including a source, a gate, and a drain, with the source of the eleventh transistor connected to the first set signal end, and with the drain and the gate of the eleventh transistor connected to the signal input end.

The present invention further provides a display device including a scan control line driving module and a display panel having a plurality of scan control lines connected to the scan control line driving module.

The scan control line driving module includes a timing sequence controller, a first grade scan control line driving unit, a second grade scan control line driving unit, and a third grade scan control line driving unit.

The timing sequence controller is adapted to output a first timing sequence control signal and a second timing sequence control signal.

The first grade scan control line driving unit includes a first timing sequence control end and a second timing sequence control end, the first timing sequence control end of the first grade scan control line driving unit receives the first timing sequence control signal, the second timing sequence control end of the first grade scan control line driving unit receives the second timing sequence control signal, and the first grade scan control line driving unit outputs a first grade scan signal to the second grade scan control line driving unit.

The second grade scan control line driving unit includes a first timing sequence control end and a second timing sequence control end, the first timing sequence control end of the second grade scan control line driving unit receives the second timing sequence control signal, the second timing sequence control end of the second grade scan control line driving unit receives the first timing sequence control signal, and the second grade scan control line driving unit outputs a second grade scan signal to the third grade scan control line driving unit.

The third grade scan control line driving unit includes a first timing sequence control end and a second timing sequence control end, the first timing sequence control end of the third grade scan control line driving unit receives the first timing sequence control signal, the second timing sequence control end of the third grade scan control line driving unit receives the second timing sequence control signal, and the third grade scan control line driving unit outputs a scan signal.

The timing sequence controller can include a first clock signal line for outputting a first clock signal and a second clock signal line for outputting a second clock signal. The first and second clock signal lines are square signals having an identical frequency and having a phase difference of 180°.

Each of the first grade scan control line driving unit, the second grade scan control line driving unit, and the third grade scan control line driving unit can include a signal input end, a scan control line driving circuit, and a signal output end. The scan control line driving circuit is adapted to conduct a delay processing of a signal received from the signal input end under control of the first timing sequence control signal and the second timing sequence control signal. The processed signal is outputted via the signal output end.

The scan control line driving circuit can include a control module. The control module includes:

a first transistor including a source, a gate, and a drain, with the source of the first transistor connected to a first power, and with the gate of the first transistor connected to the signal input end;

a second transistor including a gate, a source, and a drain, with the drain of the first transistor connected to the gate of the second transistor, and with the source of the second transistor connected to a first reset signal end;

a third transistor including a source, a drain, and a gate, with the source of the third transistor connected to the gate of the second transistor, with the drain of the third transistor connected to a second power, and with the gate of the third transistor connected to the first timing sequence control end;

a third capacitor having two ends respectively connected to the gate and the drain of the second transistor; and

a fourth transistor including a source, a drain, and a gate, with the drain of the second transistor connected to the source of the fourth transistor, and with the gate and the drain of the fourth transistor connected to second timing sequence control end.

The scan control line driving circuit can further include an output reset module. The output reset module includes:

a fifth transistor including a source, a gate, and a drain, with the source of the fifth transistor connected to the first power, with the gate of the fifth transistor connected to the first reset signal end, with the drain of the fifth transistor connected to a second reset signal end;

a sixth transistor including a source, a gate, and a drain, with the source of the sixth transistor connected to the first power, with the gate of the sixth transistor connected to the first set signal end, with the drain of the sixth transistor connected to the drain of the fifth transistor;

a second capacitor having two ends respectively connected to the source and the drain of the sixth transistor; and

a seventh transistor including a source, a gate, and a drain, with the source of the seventh transistor connected to the first power, with the gate of the seventh transistor connected to the drain of the sixth transistor, and with the drain of the seventh transistor connected to the signal output end.

The scan control line driving circuit can further include an output set module. The output set module includes:

an eighth transistor including a source, a gate, and a drain, with the source of the eighth transistor connected to the signal output end, with the drain of the eighth transistor connected to the first timing sequence control end;

a ninth transistor including a source, a gate, and a drain, with the gate of the eighth transistor connected to the drain of the ninth transistor, with the gate of the ninth transistor connected to a second power;

a first capacitor having two ends respectively connected to the source and the gate of the eighth capacitor;

a tenth transistor including a source, a gate, and a drain, with the source of the ninth transistor connected to the drain of the tenth transistor, with the gate of the tenth transistor connected to the second power source, and with the source of the tenth transistor connected to the second reset signal end and the first set signal end; and

an eleventh transistor including a source, a gate, and a drain, with the source of the eleventh transistor connected to the first set signal end, and with the drain and the gate of the eleventh transistor connected to the signal input end.

Each scan control line driving unit of the scan control line driving module according to the present invention includes only two control input ends. Such a design can reduce the complexity of the scan control line driving module, and the space for wires can be greatly reduced by reducing the control signals, permitting the display device to have a narrower frame.

The present invention will become clearer in light of the following detailed description of illustrative embodiments of this invention described in connection with the drawings.

### DESCRIPTION OF THE DRAWINGS

FIG. 1 is a diagram illustrating a scan control line driving module according to the present invention.

FIG. 2 is a diagram illustrating a display device according to the present invention.

FIG. 3 is a circuitry of the scan control line driving module according to the present invention.

FIG. 4 is a timing sequence of the scan control line driving module according to the present invention.

### DETAILED DESCRIPTION OF THE INVENTION

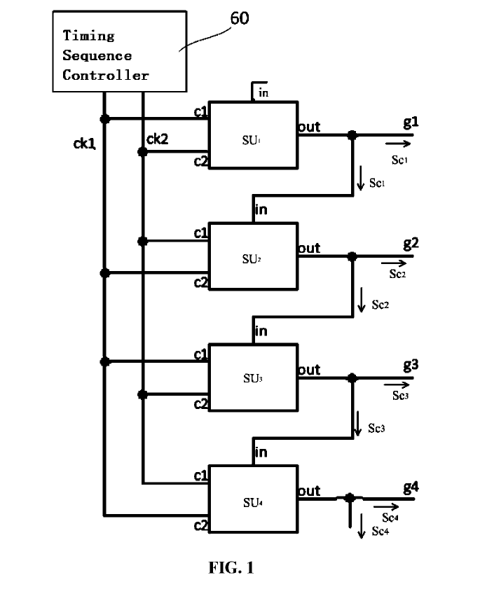

With reference to FIG. 1, a scan control line driving module according to the present invention includes a timing sequence controller 60 and a plurality of scan control line driving units SUᵢ (where i is a positive integer) connected to each other in series.

With reference to FIGS. 1, 2, and 4, a first grade scan control line driving unit SU₁ includes a first timing sequence control end c1 for receiving a first timing sequence control signal and a second timing sequence control end c2 for receiving a second timing sequence control signal. The first grade scan control line driving unit SU₁ outputs a first grade scan signal Sc₁ to a panel display module 40 and a second grade scan control line driving unit SU₂ under control by the first timing sequence control signal and the second timing sequence control signal.

The second grade scan control line driving unit SU₂ includes a first timing sequence control end c1 for receiving the second timing sequence control signal and a second timing sequence control end c2 for receiving the first timing sequence control signal. The second grade scan control line driving unit SU₂ outputs a second grade scan signal Sc₂ to the panel display module 40 and a third grade scan control line driving unit SU₃ under control by the first timing sequence control signal and the second timing sequence control signal.

The third grade scan control line driving unit SU₃ includes a first timing sequence control end c1 for receiving the first timing sequence control signal and a second timing sequence control end c2 for receiving the second timing sequence control signal. The third grade scan control line driving unit SU₃ outputs a third grade scan signal Sc₃ to the panel display module 40 and a fourth grade scan control line driving unit SU₄.

The fourth grade scan control line driving unit SU₄ includes a first timing sequence control end c1 for receiving the second timing sequence control signal and a second timing sequence control end c2 for receiving the first timing sequence control signal. The fourth grade scan control line driving unit SU₄ outputs a fourth grade scan signal Sc₄ to the panel display module 40 and a fifth grade scan control line driving unit SU₅ under control by the first timing sequence control signal and the second timing sequence control signal.

Specifically, an odd-numbered grade scan control line driving unit SUⱼ (j is an odd number larger than zero) includes a first timing sequence control end c1 for receiving the first timing sequence control signal and a second timing sequence control end c2 for receiving the second timing sequence control signal. The odd-numbered grade scan control line driving unit SUⱼ outputs a j-grade scan signal Scⱼ to the panel display module 40 and a j+1-grade scan control line driving unit SUⱼ₊₁ under control by the first timing sequence control signal and the second timing sequence control signal.

An even-numbered grade scan control line driving unit SUₖ (k is an even number larger than zero) includes a first timing sequence control end c1 for receiving the second timing sequence control signal and a second timing sequence control end c2 for receiving the first timing sequence control signal. The even-numbered grade scan control line driving unit SUₖ outputs a k-grade scan signal Scₖ to the panel display module 40 and a k+1-grade scan control line driving unit SUₖ₊₁ under control by the first timing sequence control signal and the second timing sequence control signal.

In a preferred example of the present invention, the timing sequence controller 60 includes a first clock signal line ck1 and a second clock signal line ck2. The first clock signal line ck1 is connected to the first timing sequence control end c1 of the odd-numbered grade scan control line driving unit SUⱼ and is connected to the second timing sequence control end c2 of the even-numbered scan control line driving unit SUₖ. The timing sequence controller 60 provides the first timing sequence control signal to the scan control line driving unit SUᵢ through the first clock signal line ck1. The second clock signal line ck2 is connected to the second timing sequence control end c2 of the odd-numbered grade scan control line driving unit SUⱼ and is connected to the first timing sequence control end c1 of the even-numbered scan control line driving unit SUₖ. The timing sequence controller 60 provides the second timing sequence control signal to the scan control line driving unit SU, through the second clock signal line ck2.

The first clock signal line ck1 and the second clock signal line ck2 respectively provide a first timing sequence control signal and a second timing sequence control signal to scan control line driving unit SUᵢ of each grade. The first and second clock signal lines ck1 and ck2 are square signals having an identical frequency and having a phase difference of 180°.

In the technical solution of the present invention, the scan control line driving unit SUᵢ includes only two control ends (the first timing sequence control end c1 and the second timing sequence control end c2). A scan control line driving module formed by the scan control line driving unit SUᵢ only requires the timing sequence controller 60 to provide two control signals through the first clock signal line ck1 and the second clock signal line ck2. Such a design can reduce the complexity of the scan control line driving module, and the space for wires can be greatly reduced by reducing the control signals, permitting the display device to have a narrower frame.

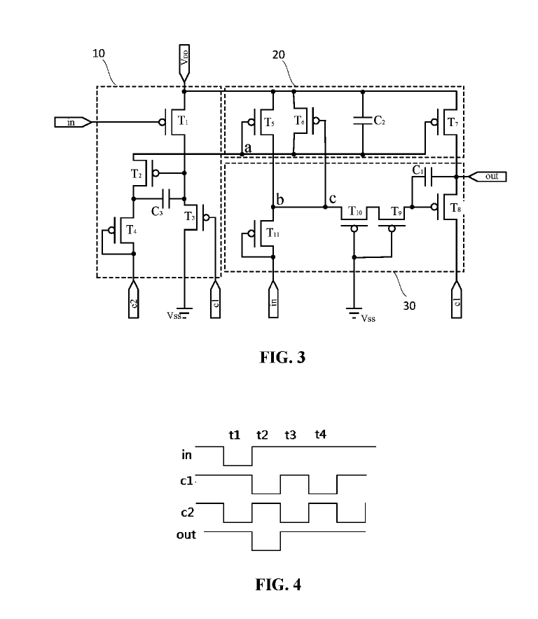

FIG. 3 is a circuitry of the scan control line driving module according to the present invention. As shown in FIG. 3, the scan control line driving unit SUᵢ includes a signal input end in, a first timing sequence control end c1, a second timing sequence control end c2, a signal output end out, and a scan control line driving circuit. The scan control line driving circuit includes a control module 10, an output reset module 20, and an output set module 30. The scan control line driving circuit is controlled by the signals received by the first timing sequence control end c1 and the second timing sequence control end c2. The scan control line driving circuit uses the signal input end in to receive the scan signal from the previous-grade scan control line driving unit SUᵢ₋₁. The received scan signal is processed by a delay processing, and the processed signal is outputted via the signal output end out.

As shown in FIG. 3, the control module 10 includes a first transistor T₁ having a source connected to a first power V_{DD}. A gate of the first transistor T₁ is connected to the signal input end in. A drain of the first transistor T₁ is connected to a gate of a second transistor T₂. A source of the second transistor T₂ is connected to a first reset signal end a. A drain of the second transistor T₂ is connected to a source of a fourth transistor T₄. A third capacitor C₃ has two ends respectively connected to the gate and the drain of the second transistor T₂. A gate and a drain of the fourth transistor T₄ are connected to second timing sequence control end c2. A source of a third transistor T₃ is connected to the gate of the second transistor T₂. A drain of the third transistor T₃ is connected to a second power Vss. A gate of the third transistor T₃ is connected to the first timing sequence control end c1.

As shown in FIG. 3, the output reset module 20 includes a fifth transistor T₅ having a source connected to the first power V_{DD}. A gate of the fifth transistor T₅ is connected to the first reset signal end a. A drain of the fifth transistor T₅ is connected to a second reset signal end b. A source of a sixth transistor T₆ is connected to the first power V_{DD}. A gate of the sixth transistor T₆ is connected to the first set signal end c. A drain of the sixth transistor T₆ is connected to the drain of the fifth transistor T₅. A second capacitor C₂ has two ends respectively connected to a source and the drain of the sixth transistor T₆. A source of a seventh transistor T₇ is connected to the first power V_{DD}. A gate of the seventh transistor T₇ is connected to the drain of the sixth transistor T₆. A drain of the seventh transistor T₇ is connected to the signal output end out.

As shown in FIG. 3, the output set module 30 includes an eighth transistor T₈ having a source connected to the signal output end out. A gate of the eighth transistor T₈ is connected to a drain of the ninth transistor T₉. A drain of the eighth transistor T₈ is connected to the first timing sequence control end c1. A first capacitor C₁ has two ends respectively connected to the source and the gate of the eighth transistor T₈. A gate of the ninth transistor T₉ is connected to a second power V_{SS}. A source of the ninth transistor T₉ is connected to a drain of the tenth transistor T₁₀. A gate of the tenth transistor T₁₀ is connected to the second power source V_{SS}. A source of the tenth transistor T₁₀ is connected to the second reset signal end b and the first set signal end c. An eleventh transistor T₁₁ includes a source connected to the first set signal end c. A drain and a gate of the eleventh transistor T₁₁ are connected to the signal input end in.

FIG. 4 is a timing sequence of the scan control line driving module according to the present invention. The waveforms shown in FIG. 4 includes four processes t1, t2, t3, and t4. During the four processes, the output signal of the signal output end out of the scan control line driving unit completes a cycle from a setting process to a resetting process. The relation between the input and output of the scan control line driving unit during the four processes will be analyzed with reference to the waveforms shown in FIG. 4 and the circuitry shown in FIG. 3.

During the t1 process, the signal of the signal input end in is at a low level, the signal of the signal output end out is at a high level, and the signal of the second timing sequence control end c2 is at a low level. The low level of the signal input end in causes conduction of the eleventh transistor T₁₁. The conduction of the eleventh transistor T₁₁ causes the output signal of the first set signal end c to turn into a low level, which means that the first set signal is in an active state. Furthermore, since the gates of the tenth transistor T₁₀ and the eleventh transistor T₁₁ are connected to the second power V_{SS}, the tenth transistor T₁₀ and the eleventh transistor T₁₁ are always in a conductive state which causes the low level of the first set signal end c to be outputted to the gate of the eighth transistor T₈. The conduction of the eighth transistor T8 causes the signal of first timing sequence control end c1 to be directly added to the signal output end out. At this time, the signal output end out outputs a high level (a rest state). Furthermore, the two ends of the first capacitor C₁ are charged during the t1 process due to the voltage difference between the source and the gate of the eighth transistor T₈.

As mentioned above, the output set module 30 outputs an active first set signal to the output reset module 20 during the t1 process, and the low-level first set signal is added to the gate of the sixth transistor T₆ and causes conduction of the sixth transistor T₆, such that the signal of the first reset signal end a is at a high level. The high level of the first reset signal end a causes the fifth transistor T₅ and the seventh transistor T₇ to be in an off state. Thus, the junction between the output reset module 20 and the signal output end out is in a highly resistive state.

During the t2 process, the signal of the signal input end in turns into a high level, the signal of the first timing sequence control end c1 turns into a low level, and the signal of the second timing sequence control end c2 turns into a high level. The high level of the signal input end in causes non-conduction of the eleventh transistor T₁₁. However the eighth transistor T₈ is still conductive during the t2 process due to the charges stored in the first capacitor C₁ during the t1 process. At this time, the signal outputted by the signal output end out turns into a low level (a set state); namely the signal of the signal output end out is set. Due to the charges at the two ends of the first capacitor C₁, the signal of the first set signal end c is still in the active state. In this case, the state of the output reset module 20 is the same as the state in the t1 process.

Furthermore, the state of the control module 10 changes during the t2 process. Since the signal of the first timing sequence control end c1 is at a low level, the third transistor T₃ is in a conductive state. The conduction of the third transistor T₃ causes direct connection between the gate of the second transistor T₂ and the second power V_{SS}, leading to conduction of the second transistor T₂. The conduction of the second transistor T₂ causes an end of the third capacitor C₃ to be connected to the first reset signal end a and causes the other end of the third capacitor C₃ to be connected to the second power V_{SS}, leading to charging of the third capacitor C₃. This charging process causes the drain voltage of the second transistor T₂ to be larger than gate voltage. Thus, the second transistor T₂ is always in the conductive state during the following process.

During the t3 process, the signal of the signal input end in remains at the high level, the first timing sequence control end c1 turns into a high level, and the second timing sequence control end c2 turns into a low level. The control module 10 outputs an active first reset signal to the output reset module 20 during the t3 process. At this time, since the second timing sequence control end c2 is at a low level, the fourth transistor T₄ is conductive. Furthermore, the charges accumulated at the two ends of the third transistor T3 during the t2 process cause the second transistor T₂ to be in a conductive state. Due to conduction of the fourth transistor T₄ and the second transistor T₂, the signal of the first reset signal end a is at a low level; namely, the control module 10 outputs an active first reset signal to the output reset module 20.

After the output reset module 20 has received the first reset signal, the fifth transistor T₅ and the seventh transistor T₇ are in a conductive state, and the signal output end out is directly connected to the first power V_{DD}. At this time, the signal of the signal output end out turns into a high level (reset). At the same time, the output reset module 20 outputs a second reset signal to the output set module 30 via the second reset signal end b. The second reset signal is active and at a high level. The active high-level second reset signal is added to the gate of the eighth transistor T₈ to make the eighth transistor T8 to be in an off state. Furthermore, since the voltages at the two ends of the first capacitor C₁ are identical during the t3 process, the charges stored in the first capacitor C1 during the t1 process are released during the t3 process. At the same time, the low level of the first reset signal end a causes charging of the second capacitor C₂ during the t3 process.

During the t4 process, the signal of the signal input end in remains at the high level, the first timing sequence control end c1 turns into a low level, and the second timing sequence control end c2 turns into a high level. Since the signal of the first timing sequence control end c1 is at a low level during the t4 process, the third transistor T₃ is in a conductive state. The conduction of the third transistor T₃ causes the gate of the second transistor T₂ to be directly connected to the second power V_{SS}, leading to conduction of the second transistor T₂. At this time, the voltage of the first reset signal end a is decided by the second capacitor C₂ and the third capacitor C₃. When the capacitances of the second capacitor C2 and the third capacitor C3 are selected to be in an appropriate ratio, the voltage of the first reset signal end a is still at the low level. The states of the output reset module 20 and the output set module 30 during the t4 process are the same as those in the t3 process. The signal output end out is still in the reset state (high level).

In view of the foregoing, the relation between the input and the output of the scan control line driving unit is that if the signal input end in is at a low level before arrival of the falling edge of the signal of the first timing sequence control end c1, the signal output end out also outputs a low level before arrival of the falling edge of the signal of the first timing sequence control end c1 until arrival of the falling edge of the signal of the second timing sequence control end c2; namely the low-level signal from the signal input end in is processed by a delay processing and is then outputted via the signal output end out. If the signal input end in remains at the high level, the signal of the signal output end out also remains at the high level.

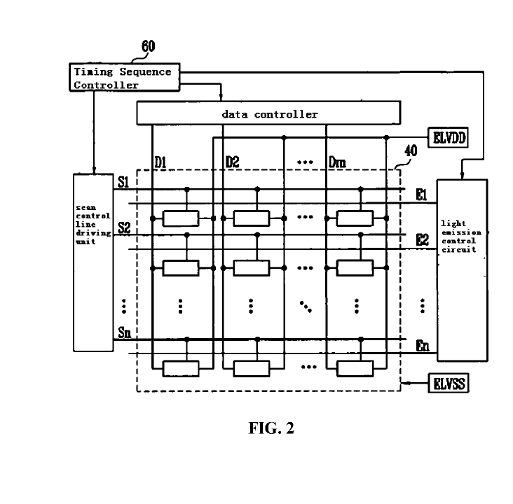

As shown in FIG. 1, the scan control line driving module includes a plurality of scan signal output ends gᵢ (i is a serial number of the scan control line) respectively corresponding to the plurality of scan control line driving unit SUᵢ. The signal output end out of scan control line driving unit SUᵢ of each grade is also connected to a corresponding one of the scan signal output ends gᵢ. FIG. 2 is a diagram illustrating a display device using the scan control line driving circuit according to the present invention. As can be seen from FIG. 2, the display device includes a scan control line driving module and a display panel 40. The display panel 40 includes n scan control lines S₁, S₂, . . . Sᵢ . . . Sₙ which are respectively connected to n signal output ends gᵢ of the scan control line driving module.

The scan control line driving unit SUᵢ includes only two control input ends (the first timing sequence control end c1 and the second timing sequence control end c2). A scan control line driving module formed by the scan control line driving units SUᵢ only requires the timing sequence controller 60 to provide two control signals through the first clock signal line ck1 and the second clock signal line ck2. Such a design can reduce the complexity of the scan control line driving module, and the space for wires can be greatly reduced by reducing the control signals, permitting the display device to have a narrower frame.

Thus since the illustrative embodiments disclosed herein may be embodied in other specific forms without departing from the spirit or general characteristics thereof, some of which forms have been indicated, the embodiments described herein are to be considered in all respects illustrative and not restrictive. The scope is to be indicated by the appended claims, rather than by the foregoing description, and all changes which come within the meaning and range of equivalency of the claims are intended to be embraced therein.

1. A scan control line driving module comprising a timing sequence controller, a first grade scan control line driving unit, a second grade scan control line driving unit, and a third grade scan control line driving unit,
wherein the timing sequence controller is adapted to output a first timing sequence control signal and a second timing sequence control signal,
wherein the first grade scan control line driving unit includes a first timing sequence control end and a second timing sequence control end, the first timing sequence control end of the first grade scan control line driving unit receives the first timing sequence control signal, the second timing sequence control end of the first grade scan control line driving unit receives the second timing sequence control signal, and the first grade scan control line driving unit outputs a first grade scan signal to the second grade scan control line driving unit,
wherein the second grade scan control line driving unit includes a first timing sequence control end and a second timing sequence control end, the first timing sequence control end of the second grade scan control line driving unit receives the second timing sequence control signal, the second timing sequence control end of the second grade scan control line driving unit receives the first timing sequence control signal, and the second grade scan control line driving unit outputs a second grade scan signal to the third grade scan control line driving unit, and
wherein the third grade scan control line driving unit includes a first timing sequence control end and a second timing sequence control end, the first timing sequence control end of the third grade scan control line driving unit receives the first timing sequence control signal, the second timing sequence control end of the third grade scan control line driving unit receives the second timing sequence control signal, and the third grade scan control line driving unit outputs a scan signal.

2. The scan control line driving module as claimed in claim 1, wherein the timing sequence controller includes a first clock signal line for outputting a first clock signal and a second clock signal line for outputting a second clock signal, and wherein the first and second clock signal lines are square signals having an identical frequency and having a phase difference of 180°.

3. The scan control line driving module as claimed in claim 1, wherein each of the first grade scan control line driving unit, the second grade scan control line driving unit, and the third grade scan control line driving unit includes a signal input end, a scan control line driving circuit, and a signal output end, wherein the scan control line driving circuit is adapted to conduct a delay processing of a signal received from the signal input end under control of the first timing sequence control signal and the second timing sequence control signal, and wherein the processed signal is outputted via the signal output end.

4. The scan control line driving module as claimed in claim 3, with the scan control line driving circuit including a control module, with the control module including:
a first transistor including a source, a gate, and a drain, with the source of the first transistor connected to a first power, and with the gate of the first transistor connected to the signal input end;
a second transistor including a gate, a source, and a drain, with the drain of the first transistor connected to the gate of the second transistor, and with the source of the second transistor connected to a first reset signal end;
a third transistor including a source, a drain, and a gate, with the source of the third transistor connected to the gate of the second transistor, with the drain of the third transistor connected to a second power, and with the gate of the third transistor connected to the first timing sequence control end;
a third capacitor having two ends respectively connected to the gate and the drain of the second transistor; and
a fourth transistor including a source, a drain, and a gate, with the drain of the second transistor connected to the source of the fourth transistor, and with the gate and the drain of the fourth transistor connected to second timing sequence control end.

5. The scan control line driving module as claimed in claim 4, with the scan control line driving circuit further including an output reset module, with the output reset module including:
a fifth transistor including a source, a gate, and a drain, with the source of the fifth transistor connected to the first power, with the gate of the fifth transistor connected to the first reset signal end, with the drain of the fifth transistor connected to a second reset signal end;
a sixth transistor including a source, a gate, and a drain, with the source of the sixth transistor connected to the first power, with the gate of the sixth transistor connected to the first set signal end, with the drain of the sixth transistor connected to the drain of the fifth transistor;
a second capacitor having two ends respectively connected to the source and the drain of the sixth transistor; and
a seventh transistor including a source, a gate, and a drain, with the source of the seventh transistor connected to the first power, with the gate of the seventh transistor connected to the drain of the sixth transistor, and with the drain of the seventh transistor connected to the signal output end.

6. The scan control line driving module as claimed in claim 5, with the scan control line driving circuit further including an output set module, with the output set module including:
an eighth transistor including a source, a gate, and a drain, with the source of the eighth transistor connected to the signal output end, with the drain of the eighth transistor connected to the first timing sequence control end;
a ninth transistor including a source, a gate, and a drain, with the gate of the eighth transistor connected to the drain of the ninth transistor, with the gate of the ninth transistor connected to a second power;
a first capacitor having two ends respectively connected to the source and the gate of the eighth capacitor;
a tenth transistor including a source, a gate, and a drain, with the source of the ninth transistor connected to the drain of the tenth transistor, with the gate of the tenth transistor connected to the second power source, and with the source of the tenth transistor connected to the second reset signal end and the first set signal end; and
an eleventh transistor including a source, a gate, and a drain, with the source of the eleventh transistor connected to the first set signal end, and with the drain and the gate of the eleventh transistor connected to the signal input end.

7. A display device comprising a scan control line driving module and a display panel having a plurality of scan control lines connected to the scan control line driving module,
wherein the scan control line driving module includes a timing sequence controller, a first grade scan control line driving unit, a second grade scan control line driving unit, and a third grade scan control line driving unit,
wherein the timing sequence controller is adapted to output a first timing sequence control signal and a second timing sequence control signal,
wherein the first grade scan control line driving unit includes a first timing sequence control end and a second timing sequence control end, the first timing sequence control end of the first grade scan control line driving unit receives the first timing sequence control signal, the second timing sequence control end of the first grade scan control line driving unit receives the second timing sequence control signal, and the first grade scan control line driving unit outputs a first grade scan signal to the second grade scan control line driving unit,
wherein the second grade scan control line driving unit includes a first timing sequence control end and a second timing sequence control end, the first timing sequence control end of the second grade scan control line driving unit receives the second timing sequence control signal, the second timing sequence control end of the second grade scan control line driving unit receives the first timing sequence control signal, and the second grade scan control line driving unit outputs a second grade scan signal to the third grade scan control line driving unit, and
wherein the third grade scan control line driving unit includes a first timing sequence control end and a second timing sequence control end, the first timing sequence control end of the third grade scan control line driving unit receives the first timing sequence control signal, the second timing sequence control end of the third grade scan control line driving unit receives the second timing sequence control signal, and the third grade scan control line driving unit outputs a scan signal.

8. The display device as claimed in claim 7, wherein the timing sequence controller includes a first clock signal line for outputting a first clock signal and a second clock signal line for outputting a second clock signal, and wherein the first and second clock signal lines are square signals having an identical frequency and having a phase difference of 180°.

9. The display device as claimed in claim 7, wherein each of the first grade scan control line driving unit, the second grade scan control line driving unit, and the third grade scan control line driving unit includes a signal input end, a scan control line driving circuit, and a signal output end, wherein the scan control line driving circuit is adapted to conduct a delay processing of a signal received from the signal input end under control of the first timing sequence control signal and the second timing sequence control signal, and wherein the processed signal is outputted via the signal output end.

10. The display device as claimed in claim 9, with the scan control line driving circuit including a control module, with the control module including:
a first transistor including a source, a gate, and a drain, with the source of the first transistor connected to a first power, and with the gate of the first transistor connected to the signal input end;
a second transistor including a gate, a source, and a drain, with the drain of the first transistor connected to the gate of the second transistor, and with the source of the second transistor connected to a first reset signal end;
a third transistor including a source, a drain, and a gate, with the source of the third transistor connected to the gate of the second transistor, with the drain of the third transistor connected to a second power, and with the gate of the third transistor connected to the first timing sequence control end;
a third capacitor having two ends respectively connected to the gate and the drain of the second transistor; and
a fourth transistor including a source, a drain, and a gate, with the drain of the second transistor connected to the source of the fourth transistor, and with the gate and the drain of the fourth transistor connected to second timing sequence control end.

11. The display device as claimed in claim 10, with the scan control line driving circuit further including an output reset module, with the output reset module including:
a fifth transistor including a source, a gate, and a drain, with the source of the fifth transistor connected to the first power, with the gate of the fifth transistor connected to the first reset signal end, with the drain of the fifth transistor connected to a second reset signal end;
a sixth transistor including a source, a gate, and a drain, with the source of the sixth transistor connected to the first power, with the gate of the sixth transistor connected to the first set signal end, with the drain of the sixth transistor connected to the drain of the fifth transistor;
a second capacitor having two ends respectively connected to the source and the drain of the sixth transistor; and
a seventh transistor including a source, a gate, and a drain, with the source of the seventh transistor connected to the first power, with the gate of the seventh transistor connected to the drain of the sixth transistor, and with the drain of the seventh transistor connected to the signal output end.

12. The display device as claimed in claim 11, with the scan control line driving circuit further including an output set module, with the output set module including:
an eighth transistor including a source, a gate, and a drain, with the source of the eighth transistor connected to the signal output end, with the drain of the eighth transistor connected to the first timing sequence control end;
a ninth transistor including a source, a gate, and a drain, with the gate of the eighth transistor connected to the drain of the ninth transistor, with the gate of the ninth transistor connected to a second power;
a first capacitor having two ends respectively connected to the source and the gate of the eighth capacitor;
a tenth transistor including a source, a gate, and a drain, with the source of the ninth transistor connected to the drain of the tenth transistor, with the gate of the tenth transistor connected to the second power source, and with the source of the tenth transistor connected to the second reset signal end and the first set signal end; and
an eleventh transistor including a source, a gate, and a drain, with the source of the eleventh transistor connected to the first set signal end, and with the drain and the gate of the eleventh transistor connected to the signal input end.
